(19) United States
(12) Patent Application Publication
(10) Pub. No.: US 2024/0250104 A1
(43) Pub. Date: Jul. 25, 2024

(54) IMAGE SENSOR

(71) Applicant: Samsung Electronics Co., Ltd., Suwon-si (KR)

(72) Inventors: Gyunha PARK, Suwon-si (KR); Jeongsoon KANG, Suwon-si (KR); Jongeun PARK, Suwon-si (KR); Gwideok Ryan LEE, Suwon-si (KR); Dongseok CHO, Suwon-si (KR)

(73) Assignee: Samsung Electronics Co., Ltd., Suwon-si (KR)

(21) Appl. No.: 18/416,388

(22) Filed: Jan. 18, 2024

(30) Foreign Application Priority Data
Jan. 25, 2023 (KR) 10-2023-0009544

(51) Int. Cl. H01L 27/146; H01L 23/00; H04N 25/79

(52) U.S. Cl. CPC H01L 27/14634; H01L 24/08; H01L 24/80; H01L 27/1469; H01L 2224/08145; H01L 2224/80895; H01L 2224/80896; H04N 25/79

(57) ABSTRACT

Provided is an image sensor including a first structure and a second structure stacked in a vertical direction, wherein the first structure includes a first pixel region, a photoelectric conversion unit in the first pixel region, a floating diffusion region in the first pixel region, a first interlayer insulating layer on the floating diffusion region, and a first pixel pad electrically connected to the floating diffusion region, and the second structure includes a second pixel region, a source-follower transistor in the second pixel region, a second interlayer insulating layer on the source-follower transistor, and a second pixel pad electrically connected to a gate of the source-follower transistor, and the image sensor includes a coupling prevention line arranged around the first and second pixel pads and electrically connected to the source region of the source-follower transistor.

### CROSS-REFERENCE TO RELATED APPLICATION

This application is based on and claims priority under 35 U.S.C. § 119 to Korean Patent Application No. 10-2023-0009544, filed on Jan. 25, 2023, in the Korean Intellectual Property Office, the disclosure of which is incorporated by reference herein in its entirety.

### BACKGROUND

The inventive concepts relate to image sensors, and more particularly, to stack-type image sensors.

An image sensor is a device converting an optical image signal into an electrical signal. An image sensor includes a plurality of pixels, and each of the pixels includes a photodiode receiving incident light and converting the light into an electrical signal and a pixel circuit outputting a pixel signal by using electric charges generated by the photodiode. As the integrity of an image sensor increases, each pixel size is reduced. A stack-type image sensor may achieve reduction in a planar area of an image sensor, improvement in a resolution, and improvement in a signal processing speed.

### SUMMARY

The inventive concepts provide image sensors, in which a coupling prevention line may shield neighboring a pixel pad and a metal wiring layer from each other with the coupling prevention line being electrically connected to a source region of a source-follower transistor so as to prevent or reduce generation of coupling capacitance between the pixel pad and the metal wiring layer.

It will be appreciated by one of ordinary skill in the art that the objectives and effects that could be achieved with the inventive concepts are not limited to what has been particularly described above and other objectives of the inventive concepts will be more clearly understood from the following detailed description.

According to some aspects of the inventive concepts, provided is an image sensor including a first structure and a second structure stacked in a vertical direction, wherein the first structure includes a first pixel region, a photoelectric conversion unit in the first pixel region, a floating diffusion region in the first pixel region, a first interlayer insulating layer on the floating diffusion region, and a first pixel pad electrically connected to the floating diffusion region, and the second structure includes a second pixel region, a source-follower transistor in the second pixel region, a second interlayer insulating layer on the source-follower transistor, and a second pixel pad electrically connected to a gate of the source-follower transistor, and the image sensor includes a coupling prevention line arranged around the first and second pixel pads and electrically connected to the source region of the source-follower transistor.

According to some aspects of the inventive concepts, there is provided an image sensor including a first substrate having a pixel region, a photoelectric conversion unit in the pixel region, a floating diffusion region in the pixel region, a first metal wiring layer on the first substrate and a first interlayer insulating layer surrounding the first metal wiring layer, a second metal wiring layer on the first interlayer insulating layer and a second interlayer insulating layer surrounding the second metal wiring layer, a source-follower transistor on the second interlayer insulating layer, a pixel pad located in the first and second interlayer insulating layers, electrically connected to the floating diffusion region via the first metal wiring layer, and electrically connected to a gate of the source-follower transistor via the second metal wiring layer, and a coupling prevention line arranged around the pixel pad and electrically connected to the source region of the source-follower transistor via the second metal wiring layer.

According to some aspects of the inventive concepts, provided is an image sensor including a first substrate having a pixel region, a photoelectric conversion unit in the pixel region, a floating diffusion region in the pixel region, a first metal wiring layer on the first substrate and a first interlayer insulating layer surrounding the first metal wiring layer, a rear surface insulating layer on the first interlayer insulating layer, a second substrate on the rear surface insulating layer, a source-follower transistor on the second substrate, a second metal wiring layer on the second substrate and a second interlayer insulating layer surrounding the second metal wiring layer, a pixel pad located in the first interlayer insulating layer and the rear surface insulating layer, electrically connected to the floating diffusion region via the first metal wiring layer, and electrically connected to a gate of the source-follower transistor via the second metal wiring layer, coupling prevention lines arranged around the pixel pad and electrically connected to the source region of the source-follower transistor via the second metal wiring layer, and a penetrating vertical via electrically connecting the pixel pad and the coupling prevention line to the second metal wiring layer by passing through the second substrate.

### BRIEF DESCRIPTION OF THE DRAWINGS

Example embodiments of the inventive concepts will be more clearly understood from the following detailed description taken in conjunction with the accompanying drawings in which:

FIG. 1 is a block diagram of an image sensor according to some example embodiments of the inventive concepts;

FIG. 2 is a circuit diagram showing an example of a pixel unit included in an image sensor according to some example embodiments of the inventive concepts;

FIG. 3 is a cross-sectional view of an image sensor corresponding to the circuit diagram of FIG. 2, according to some example embodiments of the inventive concepts;

FIGS. 4 and 5 are plan views corresponding to the image sensor of FIG. 3;

FIGS. 6 and 7 are cross-sectional views of image sensors according to some example embodiments of the inventive concepts;

FIG. 8 is a flowchart of a method of manufacturing an image sensor, according to some example embodiments of the inventive concepts;

FIGS. 9 to 11 are cross-sectional views for describing a method of manufacturing an image sensor, according to some example embodiments of the inventive concepts, according to a processing order;

FIG. 12 is a block diagram of an electronic device including a multi-camera module;

FIG. 13 is a detailed block diagram of a camera module of FIG. 12; and

FIG. 14 is a block diagram of an image sensor according to some example embodiments of the inventive concepts.

### DETAILED DESCRIPTION

Hereinafter, example embodiments of the inventive concepts will be described in detail with reference to accompanying drawings.

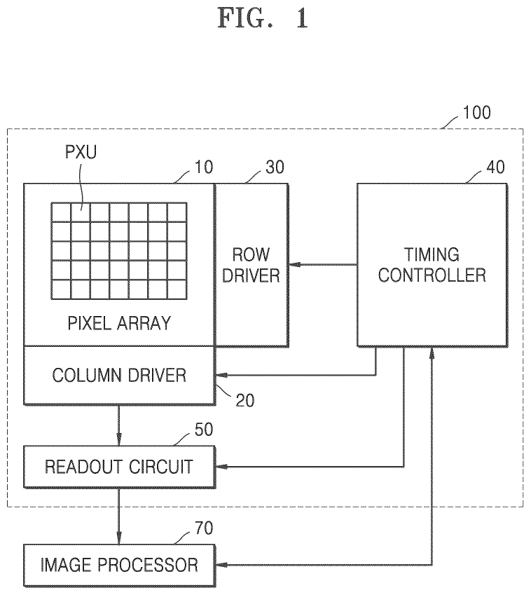

FIG. 1 is a block diagram of an image sensor 100 according to some example embodiments of the inventive concepts.

Referring to FIG. 1, the image sensor 100 according to the inventive concepts may include a pixel array 10 and a plurality of circuits for controlling the pixel array 10.

In some example embodiments, the circuits for controlling the pixel array 10 may include a column driver 20, a row driver 30, a timing controller 40, and a readout circuit 50.

The image sensor 100 may operate according to a control command received from an image processor 70, and may convert light transferred from an external object into an electrical signal and then output the electrical signal to the image processor 70. The image sensor 100 may include a complementary metal oxide semiconductor (CMOS) image sensor.

The pixel array 10 may include a plurality of pixel units (or unit pixels) PXU having a two-dimensional array structure in which pixel units PXU are arranged in a matrix form in a plurality of rows and a plurality of columns. As used herein, the term “row” denotes a set of a plurality of unit pixels arranged in the transverse direction from among the plurality of unit pixels included in the pixel array 10, and the term “column” denotes a set of a plurality of unit pixels arranged in the longitudinal direction from among the plurality of unit pixels included in the pixel array 10.

The plurality of pixel units PXU may each include a multi-pixel structure including a plurality of photodiodes. In each of the plurality of pixel units PXU, the plurality of photodiodes may receive light transferred from the object and generate electric charges. The image sensor 100 may perform an auto-focusing function by using the phase difference of pixel signals generated by the plurality of photodiodes included in each of the plurality of pixel units PXU. Each of the plurality of pixel units PXU may include a pixel circuit for generating a pixel signal from the electric charges generated by the plurality of photodiodes.

The column driver 20 may include a correlated double sampler (CDS), an analog-to-digital converter (ADC), etc. The CDS is connected to the pixel unit PXU included in a row selected by a row selection signal supplied from the row driver 30 via column lines, and may perform correlated double sampling to detect a reset voltage and a pixel voltage. The ADC may convert the reset voltage and the pixel voltage detected by the CDS into a digital signal and transfer the digital signal to the readout circuit 50.

The readout circuit 50 may include a latch or a buffer circuit capable of temporarily storing a digital signal, an amplification circuit, etc., and may generate image data by temporarily storing or amplifying the digital signal transmitted from the column driver 20. Operation timings of the column driver 20, the row driver 30, and the readout circuit 50 may be determined by the timing controller 40, and the timing controller 40 may operate according to a control command transmitted from the image processor 70.

The image processor 70 may process the image data output from the readout circuit 50 into a signal, and may output the signal to a display apparatus, etc. or may store the signal in a storage device such as a memory. For example, in some example embodiments, the image sensor 100 may be loaded in an autonomous vehicle, and the image processor 70 may process the image data into a signal and then transfer the signal to a main controller, etc. controlling the autonomous vehicle. In some example embodiments, the image sensor 100 may be loaded in security device, and the image processor 70 may process the image data into a signal and then transfer the signal to a main controller, etc. controlling an alarm signal, etc. However, example embodiments are not limited thereto.

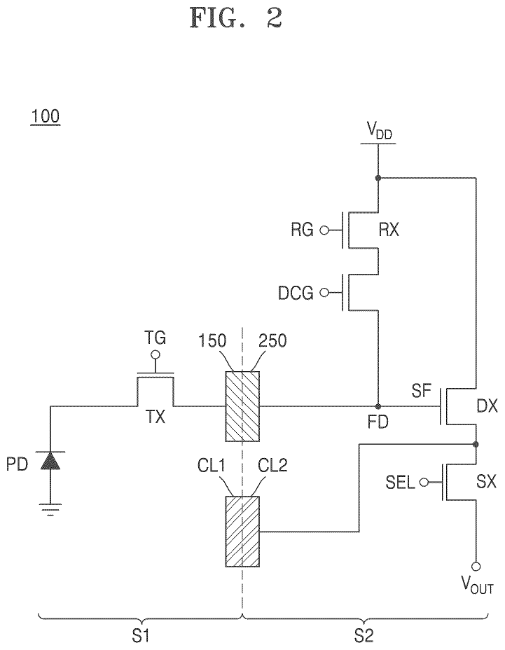

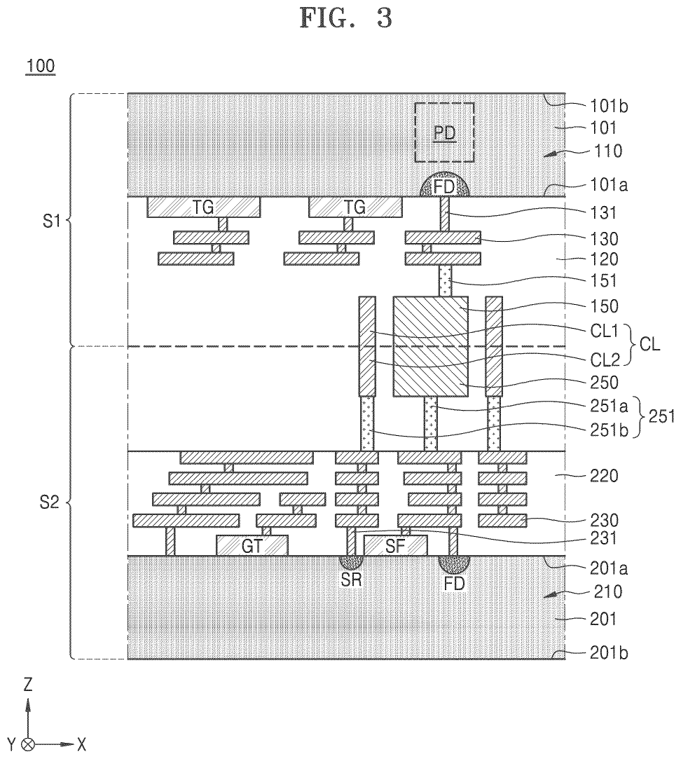

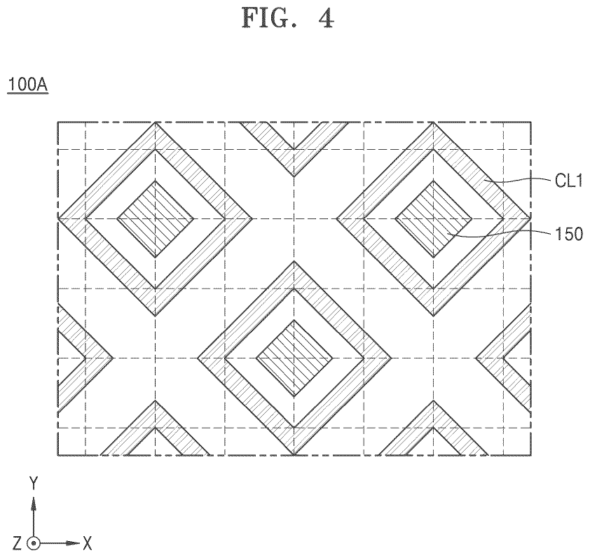

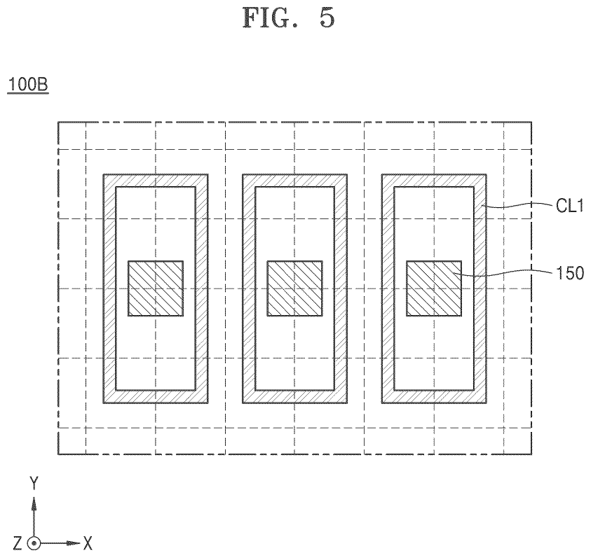

FIG. 2 is a circuit diagram shown in an example of a pixel unit included in an image sensor according to some example embodiments of the inventive concepts, FIG. 3 is a cross-sectional view of an image sensor corresponding to the circuit diagram of FIG. 2, according to some example embodiments of the inventive concepts, and FIGS. 4 and 5 are plan views corresponding to the image sensor of FIG. 3.

Referring to FIGS. 2 to 5, the image sensor 100 may include a first structure S1 and a second structure S2 that are stacked in the vertical direction (Z direction).

The image sensor 100 may include the first structure S1 and the second structure S2 on the lower surface of the first structure S1, as a stack-type structure. In some example embodiments, the image sensor 100 may further include an anti-reflection layer (not shown) on the upper surface of the first structure S1, a color filter (not shown) on the anti-reflection layer, and a micro-lens (not shown) on the color filter.

The first structure S1 may include a first substrate 101. The first substrate 101 may include a first surface 101a and a second surface 101b facing each other. The first surface 101a may be an active surface and the second surface 101b may be a non-active surface. The first substrate 101 may include a semiconductor material such as a Group IV semiconductor material, a Group III-V semiconductor material, or a Group II-VI semiconductor material. The Group IV semiconductor material may include, for example, silicon (Si), germanium (Ge), or Si-Ge. The Group III-V semiconductor material may include, for example, gallium arsenide (GaAs), indium phosphide (InP), indium arsenide (InAs), indium antimonide (InSb), or indium gallium arsenide (InGaAs). The Group II-VI semiconductor material may include, for example, zinc telluride (ZnTe) or cadmium sulfide (CdS).

The first substrate 101 of the first structure S1 may include a first pixel region 110. The first structure S1 may include a plurality of photoelectric conversion units PD in the first pixel region 110. In some example embodiments, the photoelectric conversion unit PD may include a photodiode. In this case, the photoelectric conversion unit PD may have an impurity region having a conductive type opposite to that of the first substrate 101. In some example embodiments, the photoelectric conversion unit PD may include a phototransistor, a photo-gate, or a pinned photodiode.

The first structure S1 may include a pixel isolation structure (not shown). The pixel isolation structure may electrically isolate the photoelectric conversion units PD from one another. The pixel isolation structure may penetrate through the first substrate 101 in the vertical direction (Z direction) from the first surface 101a to the second surface 101b of the first substrate 101.

The first structure S1 may include a floating diffusion region FD in the first pixel region 110. The floating diffusion region FD may be disposed in the first substrate 101 to be adjacent to (or, for example, on or directly on) the first surface 101a of the first substrate 101. The floating diffusion region FD may be an impurity region in the first substrate 101.

The first structure S1 may include a plurality of transmission gates TG on the first pixel region 110. In some example embodiments, each transmission gate TG may be arranged on the first surface 101a of the first substrate 101.

The first structure S1 may include a first interlayer insulating layer 120. The first interlayer insulating layer 120 may cover the first surface 101a of the first substrate 101 and the plurality of transmission gates TG. The first interlayer insulating layer 120 may include a multi-layered structure. The first interlayer insulating layer 120 may include, for example, silicon oxide (SiO₂), silicon nitride (SiN), or a combination thereof. In some example embodiments, the first interlayer insulating layer 120 may include a low-dielectric material having a lower dielectric constant than that of silicon oxide (SiO₂).

The first structure S1 may include a first pixel pad 150. The first pixel pad 150 may be in the first interlayer insulating layer 120 on the first pixel region 110. The first pixel pad 150 may be electrically connected to the floating diffusion region FD. The first pixel pad 150 may include a conductive material such as copper (Cu).

The first structure S1 may include a first coupling prevention line CL1. The first coupling prevention line CL1 may be arranged to surround the first pixel pad 150. The first coupling prevention line CL1 may be electrically connected to a source region SR of a source follower transistor DX. The first coupling prevention line CL1 may prevent or reduce coupling between neighboring first pixel pads 150. In some example embodiments, the first coupling prevention line CL1 may include the same material as that of the first pixel pad 150. For example, the first coupling prevention line CL1 may include a conductive material such as copper (Cu). Also, a vertical level of an uppermost surface of the first coupling prevention line CL1 may be substantially the same or the same as a vertical level of an uppermost surface of the first pixel pad 150.

The first structure S1 may include a first metal wiring layer 130 in the first interlayer insulating layer 120. The first metal wiring layer 130 may electrically connect the floating diffusion region FD to the first pixel pad 150 and may electrically connect the plurality of transmission gates TG to one another. The first structure S1 may include a first metal via 131 for electrically connecting the first metal wiring layers 130 in the vertical direction (Z direction) to one another. The first metal wiring layer 130 and the first metal via 131 may include copper (Cu), aluminum (Al), argentum (Ag), aurum (Au), titanium (Ti), tungsten (W), or a combination thereof.

The first structure S1 may include a first pixel via 151. The first pixel via 151 may electrically connect the first pixel pad 150 to the floating diffusion region FD. For example, the first pixel via 151 may electrically connect the first pixel pad 150 to the floating diffusion region FD via the first metal wiring layer 130 and the first metal via 131. In some example embodiments, the first pixel via 151 may include copper (Cu), that is, the same material as that of the first pixel pad 150. In some example embodiments, the first pixel via 151 may include a different material from that of the first pixel pad 150. For example, the first pixel via 151 may include tungsten (W) and the first pixel pad 150 may include copper (Cu).

The second structure S2 may include a second substrate 201. The second substrate 201 may include a first surface 201a and a second surface 201b facing each other. The first surface 201a may be an active surface and the second surface 201b may be a non-active surface. The second substrate 201 may include a semiconductor material such as a Group IV semiconductor material, a Group III-V semiconductor material, or a Group II-VI semiconductor material, like the first substrate 101. The second substrate 201 may include a second pixel region 210.

The second structure S2 may include a source-follower gate SF and various kinds of gates GT on the second pixel region 210. The various kinds of gates GT may include a selection gate SEL, a reset gate RG, a deformation gain gate DCG, etc. The source-follower gate SF may be included in the source-follower transistor DX, the selection gate SEL may be included in a selection transistor SX, and the reset gate RG may be included in a reset transistor RX.

The photoelectric conversion unit PD may generate electric charges, for example, electrons and holes, according to intensity of incident light. The transmission gate TG may transfer the electric charges generated by the photoelectric conversion unit PD to the floating diffusion region FD. The transmission gate TG may be a gate of a transmission transistor TX. Here, the floating diffusion region FD may accumulate and store the electric charges.

The source-follower transistor DX may generate source/drain current according to the amount of photo charges accumulated in the floating diffusion region FD. The source-follower transistor DX may be a buffer amplifier that amplifies a variation in potential in the floating diffusion region FD and outputs the amplified signal to an output line V_{OUT} via the selection transistor SX. The source-follower gate SF of the source-follower transistor DX is connected to the floating diffusion region FD, a drain region of the source-follower transistor DX is connected to a power voltage V_{DD}, and a source region SR of the source-follower transistor DX may be connected to a drain region of the selection transistor SX.

The reset transistor RX may periodically reset the charges accumulated in the floating diffusion region FD. The reset transistor RX may include the reset gate RG. A drain region of the reset transistor RX is connected to the floating diffusion region FD, and a source region of the reset transistor RX is connected to the power voltage V_{DD}. When the reset transistor RX is turned on, the power voltage V_{DD} connected to the source region of the reset transistor RX is transferred to the floating diffusion region FD. Here, the charges accumulated in the floating diffusion region FD discharge and the floating diffusion region FD may be reset.

The second structure S2 may include a second interlayer insulating layer 220. The second interlayer insulating layer 220 may cover the first surface 201a of the second substrate 201, the source-follower gate SF, and the various kinds of gates GT. The second interlayer insulating layer 220 may have a multi-layered structure. The second interlayer insulating layer 220 may include a material that is substantially the same or the same as that of the first interlayer insulating layer 120.

In some example embodiments, the second interlayer insulating layer 220 of the second structure S2 may be in contact with the first interlayer insulating layer 120 of the first structure S1. When the first interlayer insulating layer 120 and the second interlayer insulating layer 220 have the same materials, the boundary between the first interlayer insulating layer 120 and the second interlayer insulating layer 220 may not be clear.

The second structure S2 may include a second pixel pad 250. The second pixel pad 250 may be in the second interlayer insulating layer 220 on the second pixel region 210. The second pixel pad 250 may be electrically connected to the source-follower gate SF. The second pixel pad 250 may include a conductive material such as copper (Cu). The second pixel pad 250 may directly contact the first pixel pad 150. For example, copper-to-copper (Cu-to-Cu) direct bonding may be formed between the second pixel pad 250 and the first pixel pad 150.

The second structure S2 may include a second coupling prevention line CL2. The second coupling prevention line CL2 may be arranged to surround the second pixel pad 250. The second coupling prevention line CL2 may be electrically connected to the source region SR of the source-follower transistor DX. The second coupling prevention line CL2 may prevent or reduce coupling between neighboring second pixel pads 250. In some example embodiments, the second coupling prevention line CL2 may include a material that is substantially the same or the same as that of the first coupling prevention line CL1. Also, a vertical level of a lowermost surface of the second coupling prevention line CL2 may be substantially the same or the same as a vertical level of a lowermost surface of the second pixel pad 250. In some example embodiments, the contact surface between the first coupling prevention line CL1 and the second coupling prevention line CL2 may be in coplanar with the contact surface between the first pixel pad 150 and the second pixel pad 250.

The second structure S2 may include a second metal wiring layer 230 in the second interlayer insulating layer 220. The second metal wiring layer 230 may electrically connect the floating diffusion region FD to the second pixel pad 250 and may electrically connect the source-follower gate SF to the second pixel pad 250. The second structure S2 may include a second metal via 231 for electrically connecting the second metal wiring layers 230 in the vertical direction (Z direction) to one another. The second metal wiring layer 230 and the second metal via 231 may respectively have materials that are substantially the same or the same as those of the first metal wiring layer 130 and the first metal via 131.

The second structure S2 may include a second pixel via 251. Also, the second pixel via 251 may include a first vertical via 251a and a second vertical via 251b. The first vertical via 251a may electrically connect the second pixel pad 250 to the floating diffusion region FD via the second metal wiring layer 230 and the second metal via 231. Also, the first vertical via 251a may electrically connect the second pixel pad 250 to the source-follower gate SF via the second metal wiring layer 230 and the second metal via 231. The second vertical via 251b may electrically connect the second coupling prevention line CL2 to the source region SR of the source-follower transistor DX via the plurality of second metal wiring layers 230 and the plurality of second metal vias 231. That is, the second pixel via 251 may be designed not to pass through the second substrate 201. In some example embodiments, the second pixel via 251 may have a material that is substantially the same or the same as that of the first pixel via 151.

The first coupling prevention line CL1 and the second coupling prevention line CL2 may form a coupling prevention line CL. The coupling prevention line CL may have a closed line shape (for example, a shape whose segments connect or meet end to end) surrounding the periphery of the first and second pixel pads 150 and 250. For example, in a plan view, the coupling prevention line CL may have a closed square line shape. That is, when seen on a plane, an imaginary line connecting centers of neighboring first pixel pads 150 may cross two first coupling prevention lines CL1. The image sensors 100A and 100B may be substantially the same as the image sensor 100, with different shapes and/or configurations of the coupling prevention line CL1. In some example embodiments, when seen in a plan view, the coupling prevention line CL1 may be formed in a rhombus shape in an image sensor 100A, as shown in FIG. 4. For example, the shape of the coupling prevention line CL1 may mimic a boundary shape of the first and second pixel pads 150 and 250. In some example embodiments, when seen in a plan view, the coupling prevention line CL1 may be formed in a rectangular shape in an image sensor 100B, as shown in FIG. 5. However, example embodiments are not limited thereto, and the coupling prevention line CL1 may have another closed line shape, such as a circle, five point star, etc.

As the integration of an image sensor increases, each pixel size is reduced. As described above, as the pixel size has miniaturized, a stack-type structure may be applied to the image sensor in order to increase the area of the photodiode.

In general, when the floating diffusion regions are arranged adjacent to each other in an image sensor, coupling capacitance may occur around the floating diffusion regions, which leads to undesired white spot defects. Moreover, in the stack-type image sensor, the coupling capacitance between the pixel pad and the metal wiring layer caused by the Cu-to-Cu bonding method is considered to be the largest cause of the above defects. Because the vertical thickness of the stack-type image sensor is relatively large, the coupling capacitance between the pixel pad and the metal wiring layer may also increase. This may cause undesired deterioration in electrical characteristics. In order to prevent or reduce the generation of coupling capacitance, it may be designed so that the pixel pad and the metal wiring layer neighboring each other have a gap as large as possible, but the degree of freedom in arranging the pixel pad in a fine pixel structure is very limited.

Therefore, in order to address the above coupling capacitance issue, the image sensor 100 according to some example embodiments of the inventive concepts may include the coupling prevention line CL formed around the first and second pixel pads 150 and 250 and applies the voltage to the coupling prevention line CL, and thus, generation of the coupling capacitance between the first and second pixel pads 150 and 250 and the first and second metal wiring layers 130 and 230 may be reduced or effectively prevented. That is, by electrically connecting the coupling prevention line CL to the source region SR of the source-follower transistor DX and applying the voltage to the coupling prevention line CL, the effect of restricting the coupling capacitance may be increased. Otherwise, a conversion gain may be improved through the Miller effect.

Consequently, in the image sensor 100 according to the inventive concepts, the coupling prevention line CL may shield between the first and second pixel pads 150 and 250 and the first and second metal wiring layers 130 and 230, and the coupling prevention line CL may be electrically connected to the source region SR of the source-follower transistor DX so as to prevent or reduce the generation of coupling capacitance between the first and second pixel pads 150 and 250 and the first and second metal wiring layers 130 and 230 and obtain clear images.

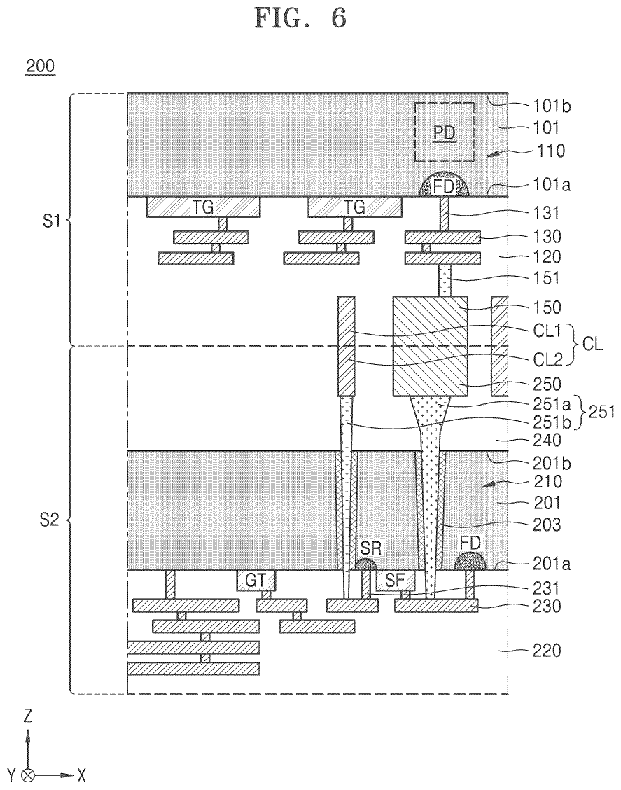

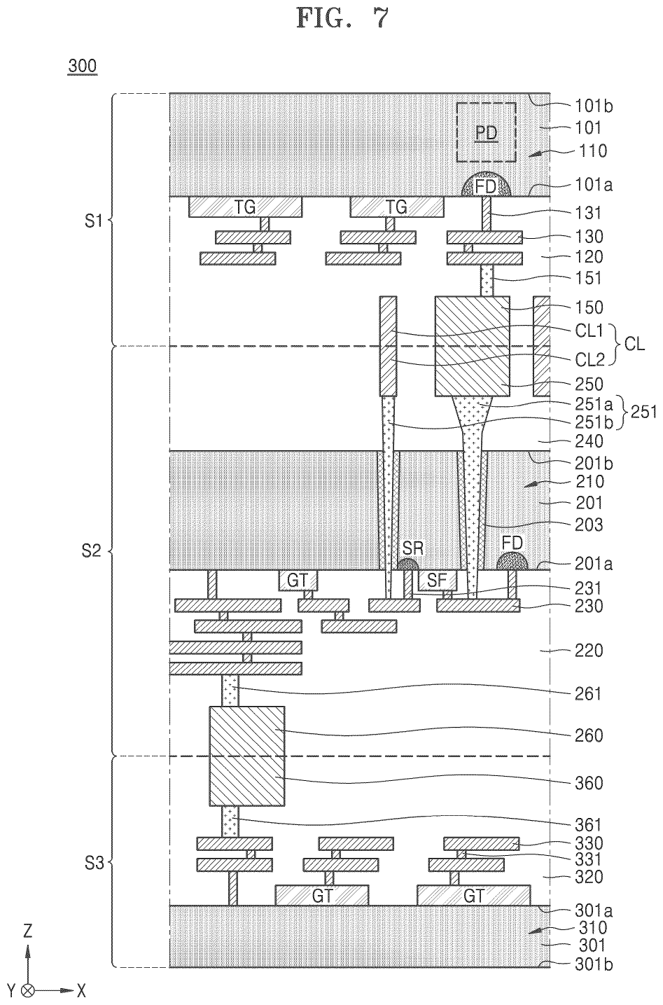

FIGS. 6 and 7 are cross-sectional views of image sensors 200 and 300 according to some example embodiments of the inventive concepts.

Most of the elements and the materials included in the elements in the image sensors 200 and 300 described below are substantially the same or the same as or similar to those of the above description provided with reference to FIGS. 2 and 3. Therefore, for convenience of description, differences from the image sensor 100 described above are provided below.

Referring to FIG. 6, the image sensor 200 may include the first structure S1 and the second structure S2 stacked in the vertical direction (Z direction).

In the image sensor 200 of some example embodiments, the second structure S2 may include the second substrate 201. The second substrate 201 may include a first surface 201a and a second surface 201b facing each other. The second surface 201b of the second substrate 201 may face the first surface 101a of the first substrate 101. That is, the first structure S1 and the second structure S2 may be stacked so that the active surface of the first substrate 101 and the non-active surface of the second substrate 201 face each other.

The second structure S2 may include a rear surface insulating layer 240 on the second surface 201b of the second substrate 201. The rear surface insulating layer 240 may have a multi-layered structure. The rear surface insulating layer 240 may include a material that is substantially the same or the same as that of the second interlayer insulating layer 220.

In some example embodiments, the rear surface insulating layer 240 of the second structure S2 may be in contact with the first interlayer insulating layer 120 of the first structure S1. When the rear surface insulating layer 240 and the first interlayer insulating layer 120 include the same materials, the boundary between the rear surface insulating layer 240 and the first interlayer insulating layer 120 may not be clear.

The second structure S2 may include the second pixel pad 250. The second pixel pad 250 may be in the rear surface insulating layer 240. The second pixel pad 250 may be electrically connected to the source-follower gate SF and the floating diffusion region FD. The second pixel pad 250 may be in contact with the first pixel pad 150. For example, Cu-to-Cu direct bonding may be formed between the second pixel pad 250 and the first pixel pad 150.

The second structure S2 may include the second coupling prevention line CL2. The second coupling prevention line CL2 may be arranged to surround the second pixel pad 250. The second coupling prevention line CL2 may be electrically connected to the source region SR of the source-follower transistor DX. In some example embodiments, the contact surface between the first coupling prevention line CL1 and the second coupling prevention line CL2 may be in coplanar with the contact surface between the first pixel pad 150 and the second pixel pad 250.

The second structure S2 may include a second pixel via 251. The second pixel via 251 may include a first vertical via 251a and a second vertical via 251b. The first vertical via 251a passes through the second substrate 201 and may electrically connect the second pixel pad 250 to the floating diffusion region FD via the second metal wiring layer 230 and the second metal via 231. Also, the first vertical via 251a passes through the second substrate 201 and may electrically connect the second pixel pad 250 to the source-follower gate SF via the second metal wiring layer 230 and the second metal via 231. The second vertical via 251b passes through the second substrate 201 and may electrically connect the second coupling prevention line CL2 to the source region SR of the source-follower transistor DX via the second metal wiring layer 230 and the second metal via 231. That is, a plurality of second pixel vias 251 may be designed to pass through the second substrate 201. In some example embodiments, a via insulating layer 203 may be formed in the second substrate 201 so as to surround the second pixel via 251.

In the image sensor 200 according to the inventive concepts, the second pixel via 251 of the second structure S2 passes through the second substrate 201 and may electrically connect the coupling prevention line CL to the source region SR of the source-follower transistor DX via the second metal wiring layer 230 and the second metal via 231. The effects achieved therefrom are the same as those provided in the above description.

Referring to FIG. 7, the image sensor 300 may include the first structure S1, the second structure S2, and a third structure S3 that are stacked in the vertical direction (Z direction).

In the image sensor 300 of some example embodiments, the third structure S3 may include a third substrate 301. The third substrate 301 may include a first surface 301a and a second surface 301b facing each other. The first surface 301a may be an active surface and the second surface 301b may be a non-active surface. The third substrate 301 may include a semiconductor material such as a Group IV semiconductor material, a Group III-V semiconductor material, or a Group II-VI semiconductor material.

The third structure S3 may further include various kinds of gates GT on a third pixel region 310. The various kinds of gates GT may form a logic circuit. The logic circuit may include at least one of a row decoder, a row driver, a column decoder, a timing generator, a CDS, an ADC, and an input/output (I/O) buffer.

The third structure S3 may include a third interlayer insulating layer 320. The third interlayer insulating layer 320 may cover the first surface 301a of the third substrate 301 and the various kinds of gates GT. The third interlayer insulating layer 320 may have a multi-layered structure. The third interlayer insulating layer 320 may include, for example, silicon oxide (SiO₂), silicon nitride (SiN), or a combination thereof. In some example embodiments, the third interlayer insulating layer 320 may include a low-dielectric material having a lower dielectric constant than that of silicon oxide (SiO₂).

The third structure S3 may include a third metal wiring layer 330 in the third interlayer insulating layer 320. Also, the third structure S3 may include a third metal via 331 electrically connecting the third metal wiring layers 330 in the vertical direction (Z direction) to one another.

The third structure S3 may include a third pixel pad 360. The third pixel pad 360 may be in the third interlayer insulating layer 320. The third pixel pad 360 may be electrically connected to various kinds of gates GT via a third pixel via 361. The third pixel pad 360 may be in contact with a connection pixel pad 260 of the second structure S2. For example, Cu-to-Cu direct bonding may be formed between the third pixel pad 360 and the connection pixel pad 260. In some example embodiments, the connection pixel pad 260 may be electrically connected to the second metal wiring layer 230 via a connection via 261.

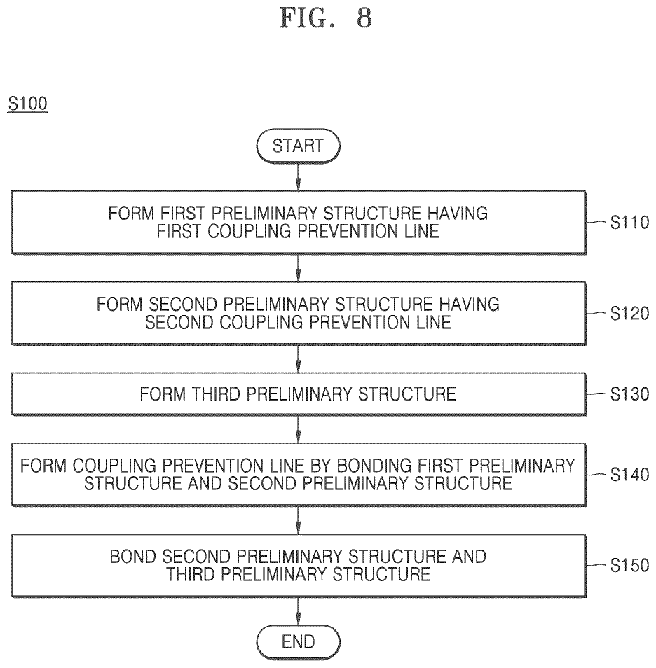

FIG. 8 is a flowchart of a method of manufacturing an image sensor, according to some example embodiments of the inventive concepts.

Referring to FIG. 8, the method of manufacturing the image sensor (S100) may include processes of step 1 to step 5 (S110 to S150).

When some example embodiments are implemented differently, a specific process order may be performed differently from the described order. For example, two consecutively described processes may be performed substantially at the same time or performed in an order opposite to the described order.

The method of manufacturing the image sensor (S100) according to the inventive concepts may include forming a first preliminary structure having a first coupling prevention line (S110), forming a second preliminary structure having a second coupling prevention line (S120), forming a third preliminary structure (S130), forming a coupling prevention line by bonding the first preliminary structure to the second preliminary structure (S140), and bonding the second preliminary structure and the third preliminary structure to each other (S150).

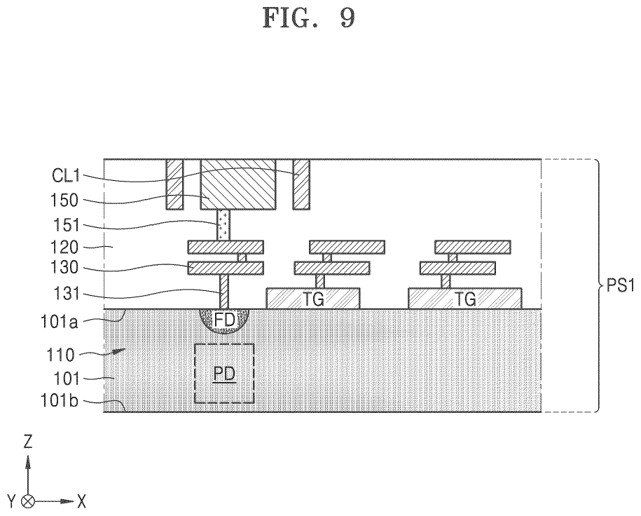

Technical features of each of the above processes (S110 to S150) are described below with reference to FIGS. 9 to 11.

FIGS. 9 to 11 are cross-sectional views for describing a method of manufacturing an image sensor, according to some example embodiments of the inventive concepts, according to a processing order.

Referring to FIG. 9, a first preliminary structure PS1 is formed. First, the first substrate 101 having the first surface 101a and the second surface 101b may be prepared. Next, a photoelectric conversion unit PD and the floating diffusion region FD may be formed in the first substrate 101 through an ion implantation process into the first surface 101a of the first substrate 101. Next, a plurality of transmission gates TG may be formed on the first surface 101a of the first substrate 101. In addition, the first interlayer insulating layer 120, the first metal wiring layer 130, the first metal via 131, the first pixel pad 150, the first pixel via 151, and the first coupling prevention line CL1 may be formed. Then, the first preliminary structure PS1 may be completely formed.

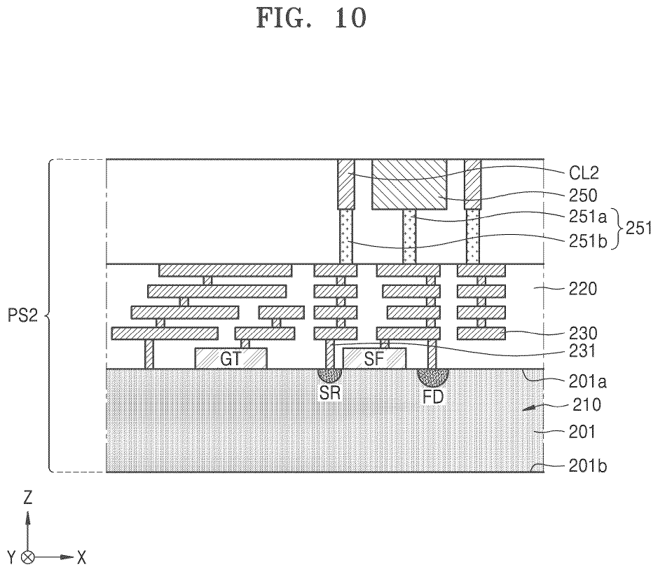

Referring to FIG. 10, a second preliminary structure PS2 is formed. First, the second substrate 201 having the first surface 201a and the second surface 201b may be prepared. Next, the floating diffusion region FD may be formed in the second substrate 201 through an ion implantation process into the first surface 201a of the second substrate 201. In addition, the source-follower gate SF may be formed on the first surface 201a of the second substrate 201. Next, the source region SR may be formed in the second substrate 201 through an ion implantation process into the first surface 201a of the second substrate 201. Next, the second interlayer insulating layer 220, the second metal wiring layer 230, the second metal via 231, the second pixel pad 250, the second pixel via 251, and the second coupling prevention line CL2 may be formed. As such, the second preliminary structure PS2 may be completely formed.

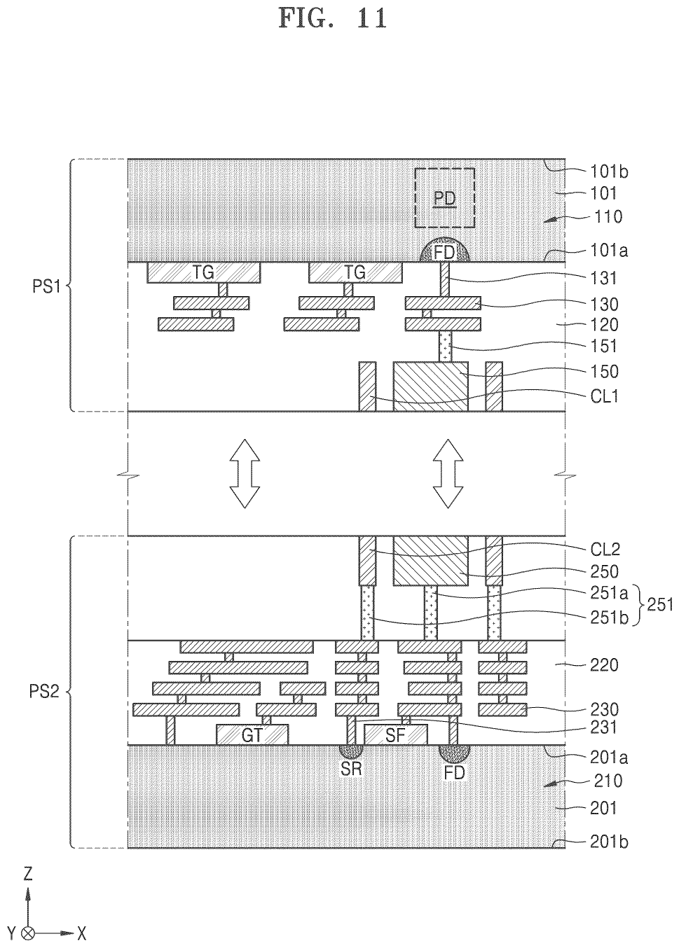

Referring to FIG. 11, the first preliminary structure PS1 and the second preliminary structure PS2 may be bonded to each other. For example, the matching features of the first preliminary structure PS1 and the second preliminary structure PS2 (such as the first coupling prevention line CL1 and the second coupling prevention line CL2) may be aligned and placed into contact, and subsequently (or, for example, simultaneously) boned (or joined, etc.). The first coupling prevention line CL1 may be in contact with the second coupling prevention line CL2, and the first pixel pad 150 may be in contact with the second pixel pad 250. Accordingly, the coupling prevention line CL (see FIG. 3) is formed by the first coupling prevention line CL1 and the second coupling prevention line CL2, and the Cu-to-Cu direct bonding may be formed between the first pixel pad 150 and the second pixel pad 250.

Although not shown in the drawings, a third preliminary structure corresponding to the third structure S3 may completed in the manner described above, and the process of bonding the third preliminary structure to the second preliminary structure PS2 is well known to one of ordinary skill in the art.

Consequently, according to the method of manufacturing the image sensor (S100) of the inventive concepts, the coupling prevention line may shield the pixel pad neighboring the coupling prevention line and the metal wiring layer, with the coupling prevention line being electrically connected to the source region of the source-follower transistor. Thus, the image sensor capable of restricting the coupling capacitance from generating between the pixel pad and the metal wiring layer may be manufactured.

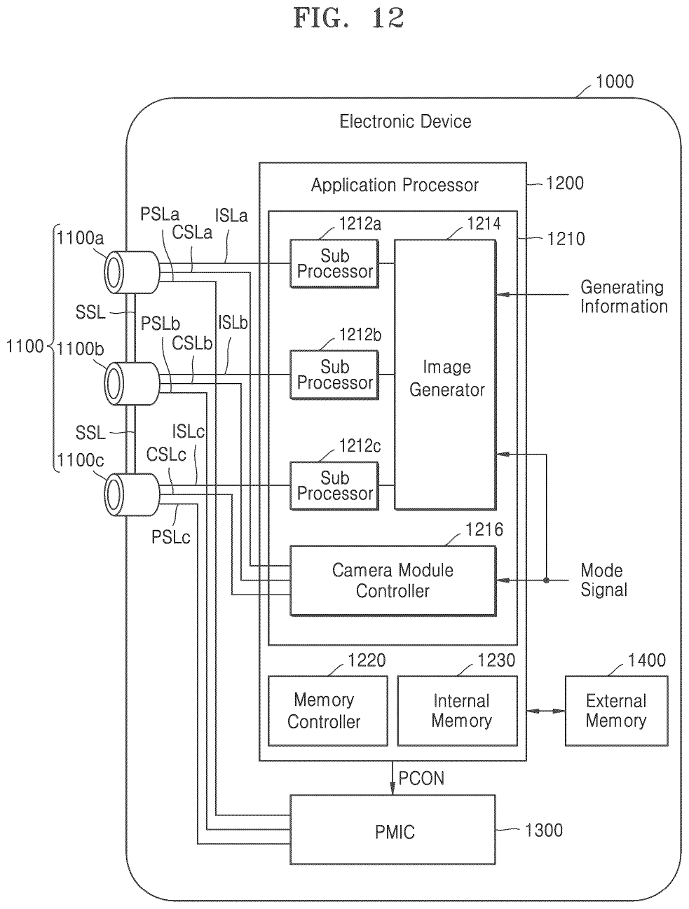

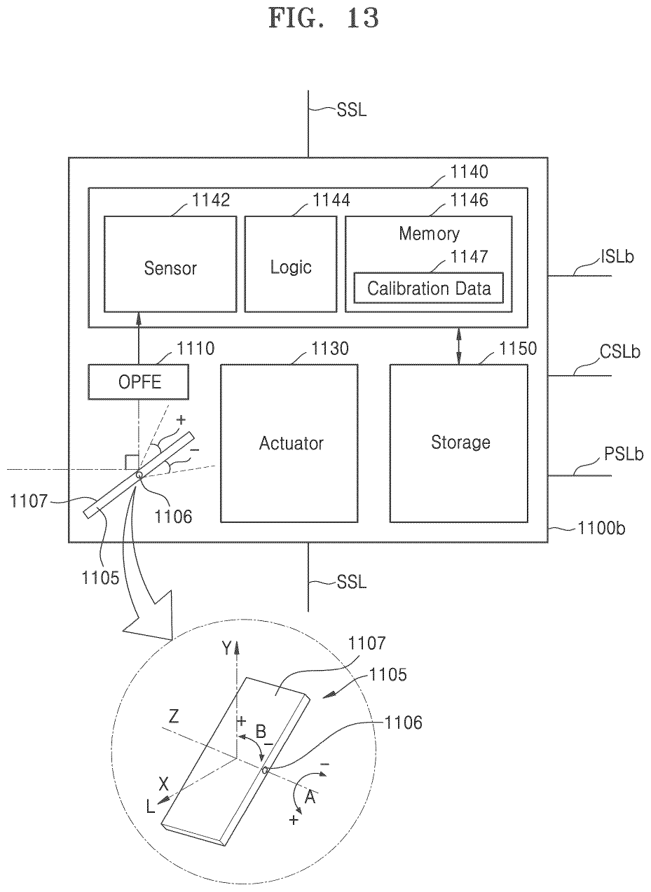

FIG. 12 is a block diagram of an electronic device 1000 including a multi-camera module, and FIG. 13 is a detailed block diagram of the camera module of FIG. 12.

Referring to FIG. 12, the electronic device 1000 may include a camera module group 1100, an application processor 1200, a power management integrated circuit (PMIC) 1300, and an external memory 1400.

The camera module group 1100 may include a plurality of camera modules 1100a, 1100b, and 1100c. Although the drawings show an example in which three camera modules 1100a, 1100b, and 1100c are arranged, example embodiments are not limited thereto. In some example embodiments, the camera module group 1100 may be modified so as to include two camera modules or n camera modules (here, n is 4 or a greater natural number).

Referring to FIG. 13, the camera module 1100b may include a prism 1105, an optical path folding element (OPFE) 1110, an actuator 1130, an image sensing device 1140, and a storage (or storage unit) 1150.

Here, detailed configuration of one camera module 1100b is described in detail below, but the description provided below may be also applied to the other camera modules 1100a and 1100c according to some example embodiments.

The prism 1105 may include a reflecting surface 1107 having a light-reflecting material and may deform a path of light L incident from outside.

In some example embodiments, the prism 1105 may change the path of the light L incident in the first direction (X-direction) into a second direction (Y-direction) that is perpendicular to the first direction (X-direction). Also, the prism 1105 may rotate the reflecting surface 1107 having the light-reflecting material about a center axis 1106 in a direction A, or about the center axis 1106 in a direction B so that the path of the light L incident in the first direction (X-direction) may be changed to the second direction (Y-direction) perpendicular to the first direction (X-direction). In this case, the OPFE 1110 may be moved in the first direction (X-direction), and the second direction (Y-direction) and a third direction (Z direction).

In some example embodiments, as shown in the drawings, the maximum rotation angle of the prism 1105 in the direction A is 15° or less in the positive A direction and is greater than 15° in the negative A direction, but some example embodiments are not limited thereto.

In some example embodiments, the prism 1105 may be moved by the angle of about 20°, or between 10° to 20° or 15° to 20° in the positive or negative B direction. Here, the moving angle is the same in the positive or negative B direction, or may be similar within a range of about 1°.

In some example embodiments, the prism 1105 may move the reflecting surface 1107 of the light-reflective material in the third direction (Z direction) that is parallel to the direction in which the center axis 1106 extends.

The OPFE 1110 may include, for example, optical lenses formed as m groups (here, m is a positive integer). Here, m lenses move in the second direction (Y-direction) and may change an optical zoom ratio of the camera module 1100b. For example, when a basic optical zoom ratio of the camera module 1100b is Z and m optical lenses included in the OPFE 1110 move, the optical zoom ratio of the camera module 1100b may be changed to 3Z, 5Z, or greater than 5Z.

The actuator 1130 may move the OPFE 1110 or the optical lens to a certain position. For example, the actuator 1130 may adjust the position of the optical lens so that the image sensor 1142 may be located at a focal length of the optical lens for exact sensing operation.

The image sensing device 1140 may include an image sensor 1142, a control logic 1144, and a memory 1146. The image sensor 1142 may sense an image of a sensing target by using the light L provided through the optical lens. The control logic 1144 may control the overall operation of the camera module 1100b. For example, the control logic 1144 may control the operations of the camera module 1100b according to a control signal provided through a control signal line CSLb.

The memory 1146 may store information that is necessary for the operation of the camera module 1100b, e.g., calibration data 1147. The calibration data 1147 may include information that is necessary for the camera module 1100b to generate image data by using the light L provided from outside. The calibration data 1147 may include, for example, information about the degree of rotation described above, information about the focal length, information about an optical axis, etc. When the camera module 1100b is implemented in the form of a multi-state camera of which the focal length is changed according to the position of the optical lens, the calibration data 1147 may include information related to focal length values of the optical lens according to each position (or state) and auto-focusing.

The storage unit 1150 may store image data sensed through the image sensor 1142. The storage unit 1150 may be disposed out of the image sensing device 1140 and may be stacked with a sensor chip included in the image sensing device 1140. In some example embodiments, the storage unit 1150 may be implemented as electrically erasable programmable read-only memory (EEPROM), however, example embodiments are not limited thereto.

Referring to FIGS. 12 and 13, in some example embodiments, each of the plurality of camera modules 1100a, 1100b, and 1100c may include the actuator 1130. Accordingly, each of the plurality of camera modules 1100a, 1100b, and 1100c may include the calibration data 1147 that is the same as or different from the others, according to the operation of the actuator 1130 included therein.

In some example embodiments, one (for example, camera module 1100b) of the plurality of camera modules 1100a, 1100b, and 1100c may be a camera module in a folded lens type including the prism 1105 and the OPFE 1110 described above, and the other camera modules (for example, camera modules 1100a and 1100c) may be vertical type camera modules not including the prism 1105 and the OPFE 1110. However, the inventive concepts are not limited thereto.

In some example embodiments, one (for example, camera module 1100c) of the plurality of camera modules 1100a, 1100b, and 1100c may be a depth camera of a vertical type, which extracts depth information by using infrared ray (IR). In this case, the application processor 1200 may generate a 3-dimensional (3D) depth image by merging image data provided from the depth camera and image data provided from the other camera module 1100a or 1100b.

In some example embodiments, at least two camera modules (e.g., camera modules 1100a and 1100b) from among the plurality of camera modules 1100a, 1100b, and 1100c may have different fields of view. In this case, for example, the optical lenses of the at least two camera modules (e.g., camera modules 1100a and 1100b) from among the plurality of camera modules 1100a, 1100b, and 1100c may be different from each other, but the inventive concepts are not limited thereto.

Also, in some example embodiments, the plurality of camera modules 1100a, 1100b, and 1100c may have different fields of view from one another. In this case, the optical lenses respectively included in the plurality of camera modules 1100a, 1100b, and 1100c may be different from one another, but the inventive concepts are not limited thereto.

In some example embodiments, the plurality of camera modules 1100a, 1100b, and 1100c may be physically isolated from one another. That is, the sensing region of one image sensor 1142 may not be divided and used by the plurality of camera modules 1100a, 1100b, and 1100c, but the plurality of camera modules 1100a, 1100b, and 1100c may each have an independent image sensor 1142 provided therein.

Referring back to FIG. 12, the application processor 1200 may include an image processing device 1210, a memory controller 1220, and an internal memory 1230. The application processor 1200 may be separately implemented from the plurality of camera modules 1100a, 1100b, and 1100c. For example, the application processor 1200 and the plurality of camera modules 1100a, 1100b, and 1100c may be separately implemented as separate semiconductor chips.

The image processing device 1210 may include a plurality of sub-image processors 1212a, 1212b, and 1212c, an image generator 1214, and a camera module controller 1216.

The image processing device 1210 may include a plurality of sub-image processors 1212a, 1212b, and 1212c, of which the number corresponds to the number of camera modules (the camera modules 1100a, 1100b, and 1100c).

The image data generated by each of the camera modules 1100a, 1100b, and 1100c may be provided to sub-image processors 1212a, 1212b, and 1212c via separate image signal lines ISLa, ISLb, and ISLc. For example, the image data generated by the camera module 1100a may be provided to the sub-image processor 1212a via the image signal line ISLa, the image data generated by the camera module 1100b may be provided to the sub-image processor 1212b via the image signal line ISLb, and the image data generated by the camera module 1100c may be provided to the sub-image processor 1212c via the image signal line ISLc. The image data transfer may be carried out by using a camera serial interface (CSI) based on a mobile industry processor interface (MIPI), for example, but is not limited thereto.

In addition, in some example embodiments, one sub-image processor may correspond to the plurality of camera modules. For example, the sub-image processor 1212a and the sub-image processor 1212c may not be separately implemented as shown in the drawings, but may be integrated as one image processor. In addition, the image data provided from the camera module 1100a and the camera module 1100c may be selected by the selection element (e.g., a multiplexer), and then, may be provided to the integrated sub-image processor.

The image data provided to each of the sub-image processors 1212a, 1212b, and 1212c may be provided to the image generator 1214. The image generator 1214 may generate an output image by using the image data provided from each of the sub-image processors 1212a, 1212b, and 1212c, according to image generating information or a mode signal.

For example, the image generator 1214 may generate the output image by merging at least parts of the image data generated by the camera modules 1100a, 1100b, and 1100c having different fields of view, according to image generating information or the mode signal. Also, the image generator 1214 may generate the output image by selecting one of pieces of image data generated by the camera modules 1100a, 1100b, and 1100c having different fields of view, according to image generating information or the mode signal.

In some example embodiments, the image generating information may include a zoom signal or a zoom factor. Also, in some example embodiments, the mode signal may be, for example, a signal based on a mode selected by a user.

When the image generating information is a zoom signal (zoom factor) and the camera modules 1100a, 1100b, and 1100c have different fields of view (angles of view) from one another, the image generator 1214 may perform different operations according to the kind of zoom signal. For example, when the zoom signal is a first signal, the image data output from the camera module 1100a is merged with the image data output from the camera module 1100c, and then, the output image may be generated by using the merged image signal and the image data output from the camera module 1100b and not used in the merge. When the zoom signal is a second signal that is different from the first signal, the image generator 1214 may not perform the image data merging, and then, may generate the output image by selecting one piece of the image data output respectively from the camera modules 1100a, 1100b, and 1100c. However, the inventive concepts are not limited thereto, and the method of processing the image data may be modified as necessary.

In some example embodiments, the image generator 1214 receives a plurality pieces of image data, of which exposure times are different from each other, from at least one of the plurality of sub-image processors 1212a, 1212b, and 1212c, and performs the high dynamic range (HDR) process on the plurality pieces of image data. Thus, merged image data having increased dynamic range may be generated.

The camera module controller 1216 may provide each of the camera modules 1100a, 1100b, and 1100c with a control signal. The control signals generated by the camera module controller 1216 may be provided to corresponding camera modules 1100a, 1100b, and 1100c via control signal lines CSLa, CSLb, and CSLc separated from one another.

One of the plurality of camera modules 1100a, 1100b, and 1100c may be designated as a master camera module (e.g., camera module 1100b) according to the image generating information including the zoom signal or the mode signal, and the other camera modules (e.g., camera modules 1100a and 1100c) may be designated as slave cameras. The information is included in the control signal and then may be provided to the corresponding camera modules 1100a, 1100b, and 1100c via the separated control signal lines CSLa, CSLb, and CSLc.

The camera module operating as a master or a slave may be changed according to the zoom factor or an operating mode signal. For example, when the angle of view of the camera module 1100a is greater than that of the camera module 1100b and the zoom factor represents low zoom magnification, the camera module 1100b may operate as the master and the camera module 1100a may operate as the slave. On the contrary, when the zoom factor represents high zoom magnification, the camera module 1100a may operate as the master and the camera module 1100b may operate as the slave.

In some example embodiments, the control signal provided to each of the camera modules 1100a, 1100b, and 1100c provided from the camera module controller 1216 may include a sync enable signal. For example, when the camera module 1100b is a master camera and the camera modules 1100a and 1100c are slave cameras, the camera module controller 1216 may transfer the sync enable signal to the camera module 1100b. The camera module 1100b provided with the sync enable signal may generate a sync signal based on the sync enable signal and may transfer the sync signal to the camera modules 1100a and 1100c via sync signal lines SSL. The camera module 1100b and the camera modules 1100a and 1100c may transfer the image data to the application processor 1200 in synchronization with the sync signal.

In some example embodiments, the control signal provided to the plurality of camera modules 1100a, 1100b, and 1100c from the camera module controller 1216 may include mode information according to the mode signal. The plurality of camera modules 1100a, 1100b, and 1100c may operate in a first operation mode and a second operation mode in relation to the sensing speed, based on the mode information.

In the first operation mode, the plurality of camera modules 1100a, 1100b, and 1100c may generate the image signal at a first speed (for example, generating an image signal of a first frame rate), encodes the image signal at a second speed that is faster than the first speed (for example, encoding the image signal of a second frame rate that is greater than the first frame rate), and transfers the encoded image signal to the application processor 1200.

The application processor 1200 may store the received image signal, that is, the encoded image signal, in the internal memory 1230 provided therein or the external memory 1400 outside the application processor 1200, and after that, reads and decodes the encoded image signal from the internal memory 1230 or the external memory 1400, and may display the image data generated based on the decoded image signal. For example, a corresponding sub-processor from among the plurality of sub-image processors 1212a, 1212b, and 1212c of the image processing device 1210 may perform the decoding, and may perform the image processing of the decoded image signal.

In the second operation mode, the plurality of camera modules 1100a, 1100b, and 1100c generates an image signal at a third speed that is slower than the first speed (for example, generating the image signal of a third frame rate that is lower than the first frame rate), and may transfer the image signal to the application processor 1200. The image signal provided to the application processor 1200 may be a signal that is not encoded. The application processor 1200 may perform the image processing of the received image signal or store the image signal in the internal memory 1230 or the external memory 1400.

The PMIC 1300 may supply the power, for example, the power voltage, to each of the plurality of camera modules 1100a, 1100b, and 1100c. For example, the PMIC 1300 may supply the first power to the camera module 1100a via a power signal line PSLa, the second power to the camera module 1100b via a power signal line PSLb, and the third power to the camera module 1100c via a power signal line PSLc, under the control of the application processor 1200.

The PMIC 1300 may generate the power corresponding to each of the plurality of camera modules 1100a, 1100b, and 1100c and may adjust the power level, in response to a power control signal PCON from the application processor 1200. The power control signal PCON may include a power adjusting signal for each operation mode of the plurality of camera modules 1100a, 1100b, and 1100c. For example, the operation mode may include a low power mode, and the power control signal PCON may include information about the camera module operating in the low-power mode and set power level. The levels of the power provided to the plurality of camera modules 1100a, 1100b, and 1100c may be equal to or different from each other. Also, the power level may be dynamically changed.

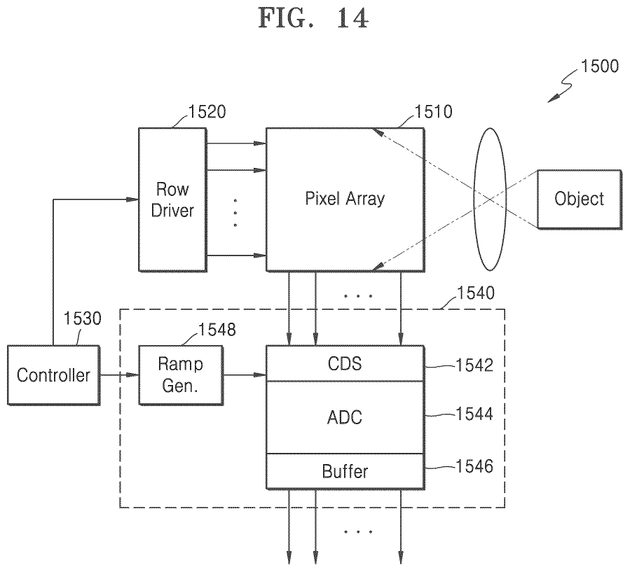

FIG. 14 is a block diagram of an image sensor 1500 according to some example embodiments of the inventive concepts.

Referring to FIG. 14, the image sensor 1500 may include a pixel array 1510, a controller 1530, a row driver 1520, and a pixel signal processor 1540.

The image sensor 1500 may include at least one of the image sensors 100, 100A, 100B, 200, and 300 described above. The pixel array 1510 may include a plurality of unit pixels that are two-dimensionally arranged, and each unit pixel may include the photoelectric conversion element. The photoelectric conversion element absorbs light to generate photo charges, and an electrical signal (output voltage) according to the generated photo charges may be provided to the pixel signal processor 1540 via a vertical signal line.

The unit pixels included in the pixel array 1510 may provide the output voltage one-by-one in the row unit, and accordingly, the unit pixels included in one row of the pixel array 1510 may be simultaneously activated according to the selection signal output from the row driver 1520. The unit pixel included in the selected row may provide the output voltage according to the absorbed light to the output line of the corresponding column.

The controller 1530 may control the row driver 1520 so that the pixel array 1510 absorbs light and accumulates the photo charges or temporarily stores the accumulated photo charges, and output the electrical signal according to the stored photo charges to outside of the pixel array 1510. Also, the controller 1530 may control the pixel signal processor 1540 so as to measure the output voltage provided from the pixel array 1510.

The pixel signal processor 1540 may include a CDS 1542, an ADC 1544, and a buffer 1546. The CDS 1542 may sample and hold the output voltage provided from the pixel array 1510.

The CDS 1542 may perform double-sampling of a certain noise level and a level according to the generated output level, and may output a level corresponding to the difference. Also, the CDS 1542 may receive an input of ramp signals generated by the ramp signal generator 1548, compare the ramp signals, and then output the comparison result.

The ADC 1544 may convert an analog signal corresponding to the level received from the CDS 1542 into a digital signal. The buffer 1546 may latch the digital signal, and the latched signal may be sequentially output to the outside of the image sensor 1500 to be transferred to the image processor (not shown).

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As described herein, any electronic devices and/or portions thereof according to any of the example embodiments may include, may be included in, and/or may be implemented by one or more instances of processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a DRAM device, storing a program of instructions, and a processor (e.g., CPU) configured to execute the program of instructions to implement the functionality and/or methods performed by some or all of any devices, systems, modules, units, controllers, circuits, architectures, and/or portions thereof according to any of the example embodiments, and/or any portions thereof.

While the inventive concepts have been particularly shown and described with reference to example embodiments thereof, it will be understood that various changes in form and details may be made therein without departing from the spirit and scope of the following claims.

What is claimed is:

1. An image sensor comprising
a first structure and a second structure stacked in a vertical direction,
the first structure comprising
a first pixel region;
a photoelectric conversion unit in the first pixel region;
a floating diffusion region in the first pixel region;
a first interlayer insulating layer on the floating diffusion region; and
a first pixel pad electrically connected to the floating diffusion region, and the second structure comprising
a second pixel region;
a source-follower transistor in the second pixel region;
a second interlayer insulating layer on the source-follower transistor; and
a second pixel pad electrically connected to a gate of the source-follower transistor; and
a coupling prevention line arranged around the first and second pixel pads and electrically connected to a source region of the source-follower transistor.

2. The image sensor of claim 1, wherein the coupling prevention line has a closed line shape surrounding the first and second pixel pads.

3. The image sensor of claim 2, wherein
a vertical level of an uppermost surface of the coupling prevention lines is the same as a vertical level of an uppermost surface of the first pixel pad, and
a vertical level of a lowermost surface of the coupling prevention lines is the same as a vertical level of a lowermost surface of the second pixel pad.

4. The image sensor of claim 3, further comprising:
a first vertical via configured to electrically connect the lowermost surface of the second pixel pad to the gate of the source-follower transistor; and
a second vertical via configured to electrically connect the lowermost surface of the coupling prevention lines to the source region of the source-follower transistor.

5. The image sensor of claim 4, wherein
the first structure is on a first substrate,
the second structure is on a second substrate, and
the first pixel pad and the second pixel pad contact with each other in a copper-to-copper (Cu-to-Cu) direct bonding method.

6. The image sensor of claim 5, wherein
an active surface of the first substrate and an active surface of the second substrate face each other,
the first and second vertical vias are in contact with a metal wiring layer on the active surface of the second substrate without passing through the second substrate, and
the metal wiring layer is electrically connected to the source-follower transistor.

7. The image sensor of claim 6, wherein the first and second pixel pads and the gate of the source-follower transistor are on the active surface of the second substrate.

8. The image sensor of claim 5, wherein
an active surface of the first substrate and a non-active surface of the second substrate face each other,
the first and second vertical vias are in contact with a metal wiring layer on the active surface of the second substrate while passing through the second substrate, and
the metal wiring layer is electrically connected to the source-follower transistor.

9. The image sensor of claim 8, wherein the first and second pixel pads are on the non-active surface of the second substrate, and the gate of the source-follower transistor is on the active surface of the second substrate.

10. The image sensor of claim 1, further comprising
a third structure on the second structure,
the third structure comprising
a third pixel region;
a logic transistor in the third pixel region; and
a third interlayer insulating layer on the logic transistor.

11. An image sensor comprising:
a first substrate having a pixel region;
a photoelectric conversion unit in the pixel region;
a floating diffusion region in the pixel region;
a first metal wiring layer on the first substrate, and a first interlayer insulating layer surrounding the first metal wiring layer;
a second metal wiring layer on the first interlayer insulating layer, and a second interlayer insulating layer surrounding the second metal wiring layer;
a source-follower transistor on the second interlayer insulating layer;
a pixel pad located in the first and second interlayer insulating layers, electrically connected to the floating diffusion region via the first metal wiring layer, and electrically connected to a gate of the source-follower transistor via the second metal wiring layer; and
a coupling prevention line arranged around the pixel pad and electrically connected to a source region of the source-follower transistor via the second metal wiring layer.

12. The image sensor of claim 11, wherein the pixel pad is formed by a first pixel pad in the first interlayer insulating layer and a second pixel pad located in the second interlayer insulating layer, the first pixel pad and the second pixel pad contacting with each other in a copper-to-copper (Cu-to-Cu) bonding method.

13. The image sensor of claim 12, wherein the coupling prevention line is formed by a first coupling prevention line in the first interlayer insulating layer and a second coupling prevention line in the second interlayer insulating layer, the first coupling prevention line and the second coupling prevention line contacting with each other in a copper-to-copper (Cu-to-Cu) bonding method.

14. The image sensor of claim 11, wherein, in plan view,
one pixel pad is surrounded by one coupling prevention line, and
one coupling prevention line has a closed square line shape.

15. The image sensor of claim 14, wherein, in plan view, an imaginary line connecting centers of neighboring pixel pads crosses two coupling prevention lines.

16. An image sensor comprising:
a first substrate having a pixel region;
a photoelectric conversion unit in the pixel region;
a floating diffusion region in the pixel region;
a first metal wiring layer on the first substrate and a first interlayer insulating layer surrounding the first metal wiring layer;
a rear surface insulating layer on the first interlayer insulating layer;
a second substrate on the rear surface insulating layer;
a source-follower transistor on the second substrate;
a second metal wiring layer on the second substrate and a second interlayer insulating layer surrounding the second metal wiring layer;
a pixel pad located in the first interlayer insulating layer and the rear surface insulating layer, electrically connected to the floating diffusion region via the first metal wiring layer, and electrically connected to a gate of the source-follower transistor via the second metal wiring layer;
coupling prevention lines arranged around the pixel pad and electrically connected to a source region of the source-follower transistor via the second metal wiring layer; and
a penetrating vertical via electrically connecting the pixel pad and the coupling prevention line to the second metal wiring layer by passing through the second substrate.

17. The image sensor of claim 16, wherein the pixel pad is formed by a first pixel pad in the first interlayer insulating layer and a second pixel pad in the rear surface insulating layer, the first pixel pad and the second pixel pad contacting with each other in a copper-to-copper (Cu-to-Cu) bonding method.

18. The image sensor of claim 16, wherein the coupling prevention line is formed by a first coupling prevention line in the first interlayer insulating layer and a second coupling prevention line in the rear surface insulating layer, the first coupling prevention line and the second coupling prevention line contacting with each other in a copper-to-copper (Cu-to-Cu) bonding method.

19. The image sensor of claim 16, wherein, when in plan view,
one pixel pad is surrounded by one coupling prevention line, and
one coupling prevention line has a closed square line shape.

20. The image sensor of claim 19, wherein, in plan view, an imaginary line connecting centers of neighboring pixel pads crosses two coupling prevention lines.
